(19) United States
(12) Patent Application Publication
(10) Pub. No.: US 2007/0004068 A1
(43) Pub. Date: Jan. 4, 2007

(54) Image display device and method of manufacturing the same

(76) Inventors: Satoko Oyaizu, Fukaya-shi (JP); Sachiko Hirahara, Fukaya-shi (JP); Nobuyuki Aoyama, Hiratsuka-shi (JP); Satoshi Ishikawa, Fukaya-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(21) Appl. No.: 11/508,203

(22) Filed: Aug. 23, 2006

Related U.S. Application Data
(63) Continuation of application No. PCT/JP05/02257, filed on Feb. 15, 2005.

(30) Foreign Application Priority Data
Feb. 24, 2004 (JP) 2004-047873

(51) Int. Cl. H01L 21/00; H01L 33/00; H01L 21/8238

(52) U.S. Cl. 438/29; 438/233; 257/88

(57) ABSTRACT

An image display device includes an envelope having a first substrate and a second substrate opposed to the first substrate with a gap, and a plurality of pixels arranged in the envelope. A plurality of spacers are arranged between the first substrate and the second substrate in the envelope to support atmospheric pressure acting on the,first and second substrates. Convexes and concaves having Ra of 0.2 to 0.6 μm and Sm of 0.02 to 0.3 mm are formed on the surfaces of the spacers.

### CROSS REFERENCE TO RELATED APPLICATIONS

This is a Continuation Application of PCT Application No. PCT/JP2005/002257, filed Feb. 15, 2005, which was published under PCT Article 21(2) in Japanese.

This application is based upon and claims the benefit of priority from prior Japanese Patent Application No. 2004-047873, filed Feb. 24, 2004, the entire contents of which are incorporated herein by reference.

### BACKGROUND OF THE INVENTION

1. Field of the Invention

The present invention relates to an image display device having substrates opposed to each other and a spacer arranged between the substrates, and to a method of manufacturing the same.

2. Description of the Related Art

In recent years, various flat image display devices have been noticed as a next generation of lightweight, thin display devices to replace cathode-ray tubes (hereinafter, referred to as CRTs). For example, a surface-conduction electron emission device (hereinafter, referred to as an SED) has been developed as a kind of a field emission device (hereinafter, referred to as an FED) that serves as a flat display device.

This SED comprises a first substrate and a second substrate that are opposed to each other across a predetermined gap. These substrates have their respective peripheral portions joined together by a rectangular sidewall, thereby constituting a vacuum envelope. Three-color phosphor layers are formed on the inner surface of the first substrate. Arranged on the inner surface of the second substrate are a large number of electron emitting elements for use as electron sources, which correspond individually to pixels, individually, and excite the phosphors. Each electron emitting element is formed of an electron emitting portion, a pair of electrodes that apply voltage to the electron emitting portion, etc.

For the SED, it is important to maintain a high degree of vacuum in a space between the first substrate and the second substrate, that is, in the vacuum envelope. If the degree of vacuum is low, the life of the electron emitting elements, and hence, the life of the device shorten inevitably. According to the display device disclosed in, for example, Jpn. Pat. Appln. KOKAI Publication No. 2001-272926, many plate-shaped or columnar spacers are arranged between the first and second substrates to bear the atmospheric pressure load acting on both substrates and to maintain the gap between the substrates. In displaying an image, in the SED, an anode voltage is applied to the phosphor layers, and electron beams emitted from the electron emitting elements are accelerated by the anode voltage and collided with the phosphor layers, whereupon the phosphor glows and displays the image. In order to obtain practical display properties, the phosphor used should be one that is similar to that of a conventional cathode-ray tube, and the anode voltage should be set to several Kv or more, preferably to 5 Kv or more.

In the SED configured as described above, when electrons having a high accelerating voltage collide with the phosphor surface, secondary electrons and reflected electrons are generated on the phosphor surface. When the gap between the first and second substrates is narrow, the secondary electrons and reflected electrons generated on the phosphor surface collide with the spacers between the substrates with a result that the spacers become charged. Accordingly, discharging is liable to occur in the vicinity of the spacers. In particular, for example, if a low resistance film is coated on the surfaces of the spacers to control the degree of movement of the electron beams, discharging is more liable to occur from the spacers. In this case, there is a possibility that the withstand voltage characteristics of the SED deteriorate.

### BRIEF SUMMARY OF THE INVENTION

An object of the present invention, which has been made in view of the above circumstances, and its object is to provide an image display device which suppresses the occurrence of discharging and improves reliability and display quality, and a method of manufacturing the apparatus.

An image display device according to an aspect of the invention comprises: an envelope having a first substrate and a second substrate opposed to the first substrate with a gap; a plurality of pixels arranged in the envelope; and a plurality of spacers arranged between the first substrate and the second substrate in the envelope to support atmospheric pressure acting on the first and second substrates, convexes and concaves having Ra of 0.2 to 0.6 μm and Sm of 0.02 to 0.3 mm being formed on surfaces of the respective spacers.

According to another aspect of the invention, there is provided an image display device comprising: an envelope having a first substrate and a second substrate opposed to the first substrate with a gap; a plurality of pixels arranged in the envelope; and a spacer structure arranged between the first substrate and the second substrate in the envelope to support atmospheric pressure acting on the first and second substrates, the spacer structure including a support substrate arranged opposite to the first and second substrates and a plurality of spacers standingly arranged on at least one surface of the support substrate, and convexes and concaves having Ra of 0.2 to 0.6 μm and Sm of 0.02 to 0.3 mm being formed on at least one of surfaces of the respective spacers and surfaces of the support substrate.

According to still another aspect, there is provided a method of manufacturing an image display device comprising an envelope having a first substrate and a second substrate opposed to the first substrate with a gap; a plurality of pixels arranged in the envelope; and a plurality of spacers arranged between the first substrate and the second substrate in the envelope to support atmospheric pressure acting on the first and second substrates, convexes and concaves having Ra of 0.2 to 0.6 μm and Sm of 0.02 to 0.3 mm being formed on surfaces of the respective spacers, the method comprising:

preparing a molding tool having a plurality of spacer forming holes; filling the spacer forming holes of the molding tool with a spacer forming material; curing the spacer forming material filled in the spacer forming holes of the molding tool and then separating the spacer forming material from the molding tool; forming spacers by baking the spacer material separated from the molding tool; and partially dissolving surfaces of the formed spacers by an acid liquid to form convexes and concaves having Ra of 0.2 to 0.6 μm and Sm of 0.02 to 0.3 mm on the entire surfaces of the spacers.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view showing an SED according to a first embodiment of the present invention.

FIG. 2 is a perspective view of the SED taken along the line II-II of FIG. 1.

FIG. 3 is a sectional view showing the SED in enlargement.

FIG. 4 is a sectional view showing a part of a spacer structure.

FIG. 5 is a sectional view showing a support substrate and a molding tool which are used to manufacture the spacer structure.

FIG. 6 is a side elevational view showing a master male mold which is used to make the molding tool.

FIG. 7 is a sectional view showing a process for making the molding tool using the master male mold.

FIG. 8 is a sectional view showing an assembly in which the molding tool is caused to come into intimate contact with the support substrate.

FIG. 9 is a sectional view showing a state in which the molding tool is opened.

FIG. 10 is a sectional view showing a spacer structure in an SED according to a second embodiment of the present invention.

FIG. 11 is a sectional view showing a part of an SED according to a third embodiment of the present invention in enlargement.

FIG. 12 is a sectional view showing a spacer structure of the SED according to the third embodiment.

### DETAILED DESCRIPTION OF THE INVENTION

A first embodiment in which the present invention is applied to an SED as a flat image display device will be described in detail with reference to the drawings.

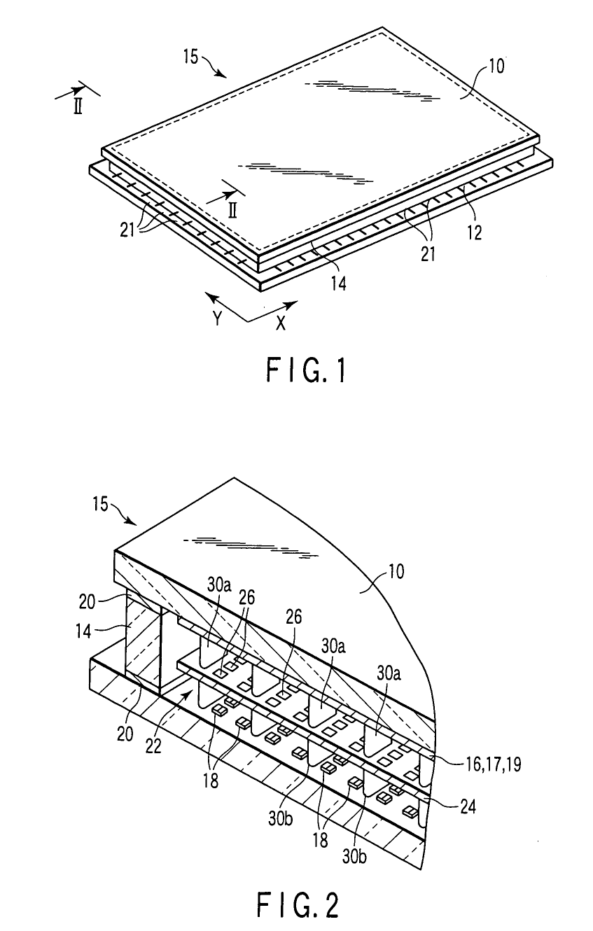

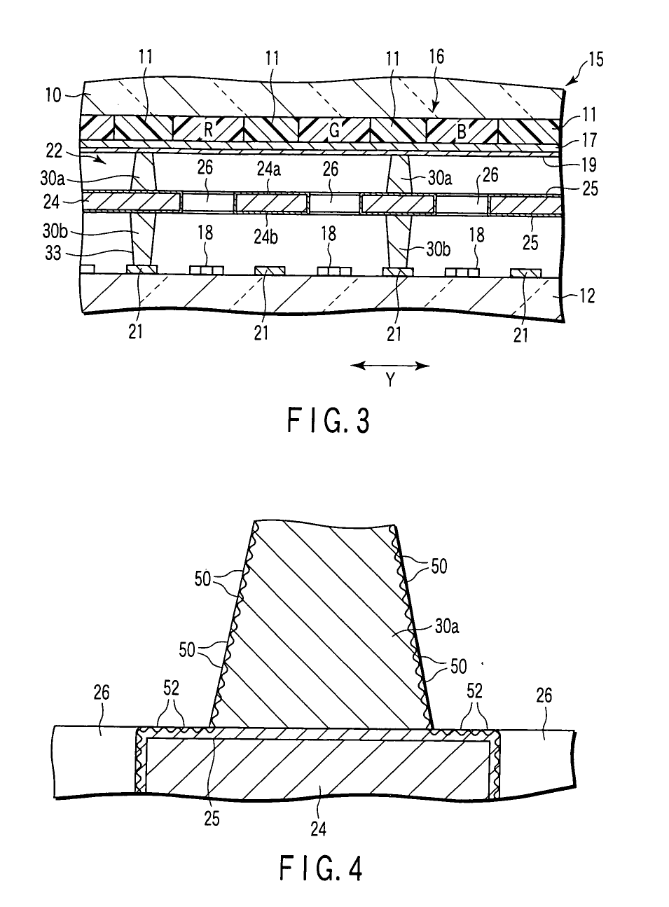

As shown in FIGS. 1 to 3, the SED includes a first substrate 10 and a second substrate 12 each composed of a rectangular glass sheet, and these substrates are arranged to face each other with a gap of about 1.0 to 2.0 mm. The peripheral edge portions of the first and second substrate 10 and 12 are joined to each other through a rectangular frame-shaped side wall 14 composed of glass, thereby forming a flat vacuum envelope 15 of which the interior is kept under vacuum.

A phosphor screen 16 acting as a phosphor surface is formed on the inner surface of the first substrate 10. The phosphor screen 16 is formed by arranging phosphor layers R, G, B, which emit red, green, and blue light, and a light shielding layer 11. These phosphor layers are formed in a stripe shape, a dot shape or a rectangular shape. A metal back 17 formed of aluminum or the like and a getter film 19 are sequentially formed on the phosphor screen 16.

Many surface conduction type electron emitting elements 18 each emitting an electron beam are arranged on the inner surface of the second substrate 12 as electron emission sources for exciting the phosphor layers R, G, B of the phosphor screen 16. These electron emitting elements 18 are arranged in plural columns and plural rows, and form pixels together with the corresponding phosphor layers. Each electron emitting element 18 includes an electron emitting unit (not shown), a pair of element electrodes for applying a voltage to the electron emitting unit, and-the like. A number of wirings 21 are arranged on the inner surface of the second substrate 12 in a matrix manner to supply potential to the electron emitting elements 18. The ends of the wirings 21 are derived outside of the flat vacuum envelope 15.

The side wall 14 acting as a joint member is sealed to the peripheral edge portion of the first substrate 10 and the peripheral edge portion of the second substrate 12 by a seal member 20, for example, a low melting point glass or a low melting point metal to join these substrates to each other.

As shown in FIGS. 2 to 4, the SED includes a spacer structure 22 arranged between the first and second substrates 10 and 12. In the embodiment, the spacer structure 22 includes a rectangular support substrate 24 arranged between the first and second substrate 10 and 12, and many columnar spacers standing on both surfaces of the support substrate integrally with it.

To describe in detail, the support substrate 24 acting as a support substrate has a first surface 24a opposing the inner surface of the first substrate 10 and a second surface 24b opposing the inner surface of the second substrate 12, and is arranged in parallel with these substrates 10 and 12. Many electron beam passage apertures 26 are formed in the support substrate 24 by etching or the like. The electron beam passage apertures 26 face the electron emitting elements 18, respectively, and are arranged in plural columns and plural rows to cause the electron beams emitted from the electron emitting elements to pass through them. When the longitudinal direction of the circuit board 15 is shown by X and the width direction thereof perpendicular to the longitudinal direction is shown by Y, the electron beam passage apertures 26 are arranged at predetermined pitches in the longitudinal direction X and the width direction Y. Here, the pitch in the width direction Y is set larger than that in the longitudinal direction X.

The support substrate 24 is formed of, for example, iron-nickel metal sheet to a thickness of 0.1 to 0.3 mm. An oxide film composed of an element constituting the metal sheet, for example, an oxide film composed of Fe₃O₄ or NiFe₂O₄ is formed on the surfaces of the support substrate 24. The surfaces 24a and 24b of the support substrate 24 and the wall surfaces defining the respective electron beam passage apertures 26 are covered with an insulating layer 25 having an effect of restricting discharging current. The insulating layer 25 is formed of a high resistance material mainly composed of glass.

Plural first spacers 30a stand on the first surface 24a of the support substrate 24 integrally with it and located between adjacent electron beam passage apertures 26, respectively. The distal ends of the first spacers 30a abut against the inner surface of the first substrate 10 interposing the getter film 19, the metal bag 17, and the light blocking layer 11 of the phosphor screen 16 therebetween.

Plural second spacers 30b stand on the second surface 24b of the support substrate 24 integrally with it and located between adjacent electron beam passage apertures 26, respectively. The distal ends of the second spacers 30b abut against the inner surface of the second substrate 12. Here, the distal ends of the respective second spacers 30b are located on the wirings 21 arranged on the inner surface of the second substrate 12. The first and second spacers 30a, 30b are arranged in the longitudinal direction X and the width direction Y at pitches several times larger than that of the electron beam passage apertures 26. The respective first and second spacers 30a, 30b are located in alignment with each other and formed integrally with the support substrate 24 so as to clamp the support substrate 24 from both sides thereof.

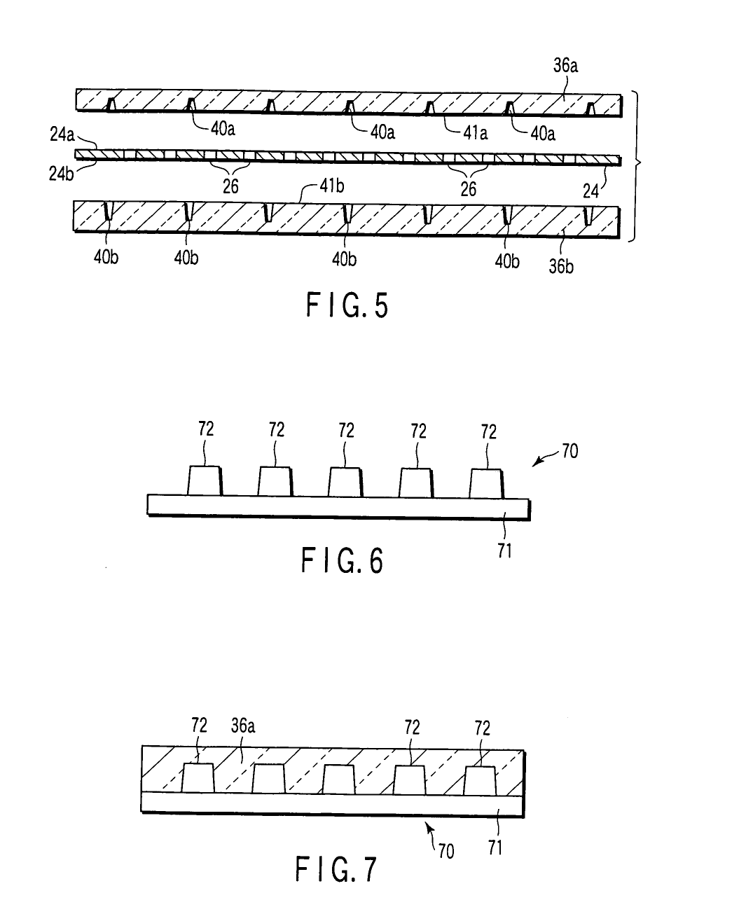

As shown in FIGS. 4 and 5, each of the first and second spacers 30a, 30b is formed to a taper shape whose diameter is gradually reduced from the support substrate 24 side toward the distal end. For example, each of the first spacers 30a has a slender elliptic cross sectional shape and is formed such that the proximal end thereof located on the support substrate 24 side has a length of about 1 mm in the longitudinal direction X, a width of about 300 μm in the width direction Y, and a height of about 0.6 mm in an extending direction. Each of the second spacers 30b has a slender elliptic cross sectional shape and is formed such that the proximal end thereof located on the support substrate 24 side has a length of about 1 mm in the longitudinal direction X, a width of about 300 μm in the width direction Y, and a height of about 0.8 mm in an extending direction. The first and second spacers 30a, 30b are arranged on the support substrate 24 in a state that the longitudinal directions of them are in agreement with the longitudinal direction X.

As shown in FIG. 4, minute convexes and concaves 50, which have an arithmetic average roughness (Ra) of 0.2 to 0.6 μm and an average interval (Sm) between concave portions and convex portions of 0.02 to 0.3 mm, are formed on the entire surfaces of the first and second spacers 30a, 30b. Minute convexes and concaves 52 having Ra of 0.2 to 0.6 μm and Sm of 0.02 to 0.3 mm are formed on the entire insulating layer 25 formed on the surface of the support substrate 24 except the region where the first and second spacers 30a, 30b stand.

The arithmetic average roughness (Ra) is a value obtained by extracting a reference length 1 from a roughness curve in its average line direction, summing the absolute values of the deviations of the extracted portion from the average line to a measuring curve, and averaging the summed values. Further, the average interval (Sm) between the convexes and concaves is obtained by extracting a reference length 1 from the roughness curve in its average line direction, finding the sum of the lengths of average lines corresponding one ridge and one valley adjacent to the ridge, and showing an average value of the sum by a unit of millimeter.

The spacer structure 22 configured as described above is arranged between the first substrate 10 and the second substrate 12. The first and second spacers 30a, 30b abut against the inner surfaces of the first substrate 10 and the second substrate 12, so that they support the atmospheric pressure acting on these substrates and keep the gap between the substrates at a predetermined value.

The SED has a voltage supply unit (not shown) for applying a voltage to the support substrate 24 and the metal back 17 of the first substrate 10. The voltage supply unit is connected to the support substrate 24 and to the metal back 17, respectively, and applies, for example, a voltage of 12 kV to the support substrate 24 and a voltage of 10 kV to the metal back 17. When an image is formed by the SED, the anode voltage is applied to the phosphor screen 16 and the metal back 17, and the electron beams emitted from the electron emitting elements 18 are accelerated by the anode voltage and caused to collide the phosphor screen 16. With this operation, the phosphor layers of the phosphor screen 16 are energized to emit lights and display images.

Next, a method of manufacturing the SED configured as described above will be explained. First, a method of manufacturing the spacer structure 22 will be explained.

As shown in FIG. 5, the support substrate 24 having a predetermined size and an upper mold 36a and a lower mold 36b each having approximately the same size as the support substrate and formed to a rectangular sheet-shape are prepared. In this case, a 0.12 mm thick metal sheet formed of Fe-50% Ni is degreased, rinsed, and dried, and then the electron beam passage apertures 26 are formed in the sheet by etching. After the metal sheet is subjected to a blacking treatment in its entirety, a solution containing glass particles is spray coated onto the surfaces of the support substrate 24 including the inner surfaces of the electron beam passage apertures 26 and died. With this operation, the support substrate 24 on which the insulating layer 25 is formed is obtained.

An upper mold 36a and a lower mold 36b acting as molding tools are formed of a transparent material through which ultraviolet rays pass, for example, transparent silicon, transparent polyethylene terephthalate, or the like, and formed in a flat sheet shape. The upper mold 36a has a flat abutment surface 41a abutted against the support substrate 24 and many bottomed spacer forming holes 40a for molding the first spacers 30a. The spacer forming holes 40a open to the abutment surface 41a of the upper mold 36a as well as are arranged at a predetermined interval. Likewise, the lower mold 36b has a flat abutment surface 41a and many bottomed spacer forming holes 40b for molding the second spacers 30b. The spacer forming holes 40b open to the abutment surface 41b of the lower mold 36b and are arranged at a predetermined interval.

The upper mold 36a and the lower mold 36b are manufactured by the following processes. The processes will be explained here as to the upper mold 36a as a typical mold. First, as shown in FIG. 6, a master male mold 70 for forming the upper mold is formed by cutting. In this case, for example, a base sheet 71 formed of brass is prepared, and one surface of the base sheet 71 is cut to form plural long columns 72 corresponding to the first spacers 30a. With this operation, the master male mold 70 is obtained. Next, as shown in FIG. 7, the upper mold 36a is obtained by filling the master male mold 70 with transparent silicon to mold the upper mold 36a and then separating it. The lower mold 36b is also formed by the same processes.

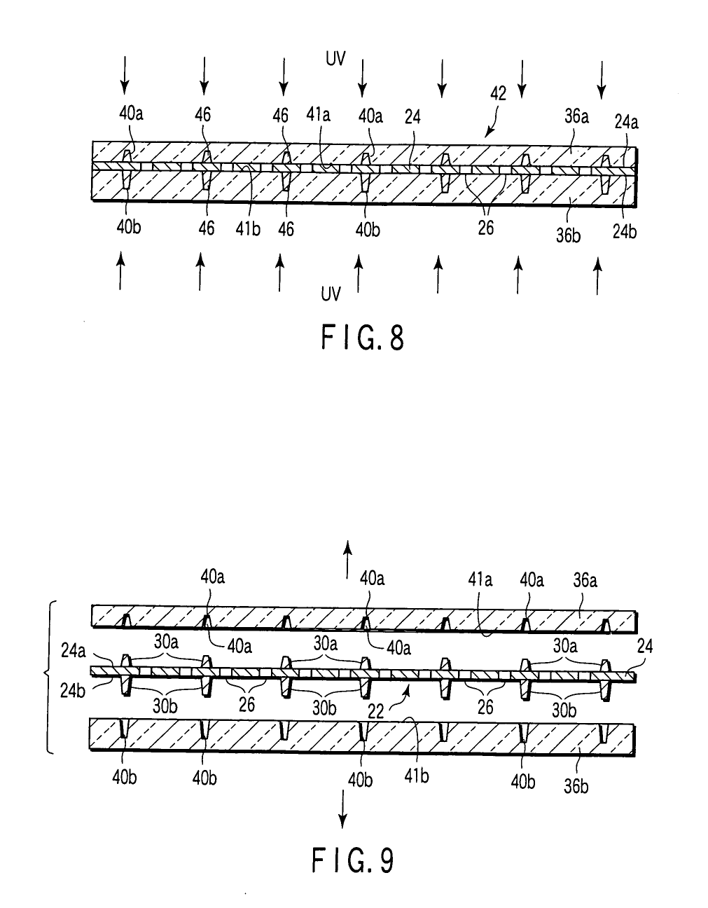

Then, as shown in FIG. 8, the spacer forming holes 40a of the upper mold 36a and the spacer forming holes 40b of the lower mold 36b are filled with a spacer forming material 46. Used as the spacer forming material 46 is a glass paste containing at least an ultraviolet ray curing type binder (organic component) and a glass filler. The specific gravity and the viscosity of the glass paste are appropriately selected.

The upper mold 36a is positioned such that the spacer forming holes 40a filled with the spacer forming material 46 oppose predetermined regions between the electron beam passage apertures 26, respectively, and the abutment surface 41a is caused to come into intimate contact with the first surface 24a of the support substrate 24. Likewise, the lower mold 36b is positioned such that the spacer forming holes 40b face predetermined regions between the electron beam passage apertures 26, respectively, and the abutment surface 41b is caused to come into intimate contact with the second surface 24b of the support substrate 24. Note that a bonding agent may be previously coated to the positions where the spacers of the support substrate 24 stand by a dispenser or print. With the above operation, an assembled body 42 including the support substrate 24, the upper mold 36a, and the lower mold 36b is configured. In the assembled body 42, the spacer forming holes 40a of the upper mold 36a and the spacer forming holes 40b of the lower mold 36b are arranged to face each other across the support substrate 24.

Ultraviolet rays (UV) are irradiated to the spacer forming material from the outside of the upper mold 36a and the lower mold 36b in the state that they come into intimate contact with the support substrate 24. Since the upper and lower molds 36a, 36b are formed of the material through which ultraviolet rays pass, the irradiated ultraviolet rays pass through the upper mold 36a and the lower mold 36b to be irradiated to the filled spacer forming material 46. With this operation, the spacer forming material 46 is cured by the ultraviolet rays. Subsequently, as shown in FIG. 9, the upper mold 36a and the lower mold 36b are separated from the support substrate 24 such that the cured spacer forming material 46 remains on the support substrate 24. The spacer forming materials 46 molded to a predetermined shape are transferred onto the surfaces of the support substrate 24 by the above process.

Next, the support substrate 24, on which the spacer forming materials 46 are arranged, is subjected to a heat treatment in a heating furnace, and the binder is evaporated from the spacer materials. Then, the spacer forming materials and the insulating layer 25 formed on the support substrate 24 are baked at about 500 to 550° C. for 30 minutes to one hour. The spacer forming material 46 and the insulating layer 25 are made to glass by the baking, and the spacer structure 22 having the first and second spacers 30a, 30b formed on the support substrate 24 can be obtained.

Subsequently, the support substrate 24 and the first and second spacers 30a, 30b each subjected to the glass baking are dipped into a 0.1 to 10 wt % hydrochloric acid liquid, so that the surfaces of the first and second spacers 30a, 30b and the surface of the insulating layer 25 of the support substrate 24 are partly dissolved. With this operation, irregular and minute convexes and concaves 50, 52 are formed on the surfaces of the first and second spacers 30a, 30b and the surface of the insulating layer 25 of the support substrate 24. The convexes and concaves 50, 52 are adjusted such that Ra is set to 0.2 to 0.6 μm and Sm is set to 0.02 to 0.3 mm by adjusting the concentration of hydrochloric acid in the solution, the temperature of the solution, and the dipping time of the support substrate and the spacers, or by adjusting the fluidity of the solution by stirring and the like.

In contrast, when the SED is manufactured, the first substrate 10, on which a phosphor screen 16 and a metal back 17 are arranged, and the second substrate 12, on which electron emitting elements 18 and wirings 21 are arranged and to which a side wall 14 is joined, are previously prepared. Subsequently, the spacer structure 22 obtained as described above is positioned and arranged on the second substrate 12. In this state, the first substrate 10, the second substrate 12, and the optical fiber core wire 2 are arranged in a vacuum chamber, the interior of the vacuum chamber is evacuated to vacuum, and then, the first substrate 10 is joined to the second substrate 12 through the side wall 14. With this operation, the SED having the spacer structure 22 is manufactured.

According to the SED configured as described above, the minute convexes and concaves 50 are formed on the surfaces of the first and second spacers 30a, 30b, whereby the surface area of the spacers can be increased, and thus the creepage distance of them can be also increased. As a result, charging of the spacers and occurrence of electric discharging can be suppressed and a resistance to voltage can be improved. Accordingly, there can be obtained an SED whose reliability and display quality are improved. Further, the minute convexes and concaves 52 are formed on the surface of the support substrate 24. Consequently, even if a low resistance film is coated on the surfaces of the spacers in order to control the amount of movement of electron beams, the low resistance film is divided by the convexes and concaves, and thus the film can be made to a film having a higher resistance. With this configuration, the electric discharging can be suppressed.

The inventors have confirmed the relation among the Ra value and the Sm value of the convexes and concaves 50 formed to the spacers, the resistance to voltage, and the strength of the spacers. Table 1 shows a result of confirmation. Here, the resistance to voltage of 50 mm square samples of the spacers was measured as well as the strength of one piece of the spacer was measured. Further, the resistance to voltage and the strength of the spacer when no convex and concave were formed on the surface of the spacer were set to 100, respectively. When convexes and concaves having Ra of 0.25 μm and Sm of 0.25 mm were formed by setting the dipping time to the hydrochloric acid liquid to 30 seconds, the resistance to voltage was 120 and the strength of the spacers was 90. Further, when convexes and concaves having Ra of 0.30 μm and Sm of 0.05 mm were formed by setting the dipping time to the hydrochloric acid liquid to 90 seconds, the resistance to voltage was 140 and the strength of the spacers was 85.

TABLE 1

| | Resistance | |
|---|---|---|
| Sample | to voltage | Strength |
| Without treatment | 100 | 100 |
| Dipping for 30 seconds | 120 | 90 |
| Dipping for 90 seconds | 140 | 85 |

As described above, when Ra and Sm are increased, the strength of the spacers is reduced although the resistance to voltage is increased. Accordingly, it is preferable to form convexes and concaves having Ra of 0.2 to 0.6 μm and Sm of 0.02 to 0.3 mm in consideration of improving the resistance to voltage and maintaining the strength of the spacers.

According to the embodiment described above, the minute convexes and concaves 50 are formed on the surfaces of the spacers after they are removed from the molding tool. As a consequence, the minute convexes and concaves can be more easily and less expensively formed as compared with a case that the minute convexes and concaves are formed on the surfaces of the spacers by using a molding tool on which convexes and concaves are formed.

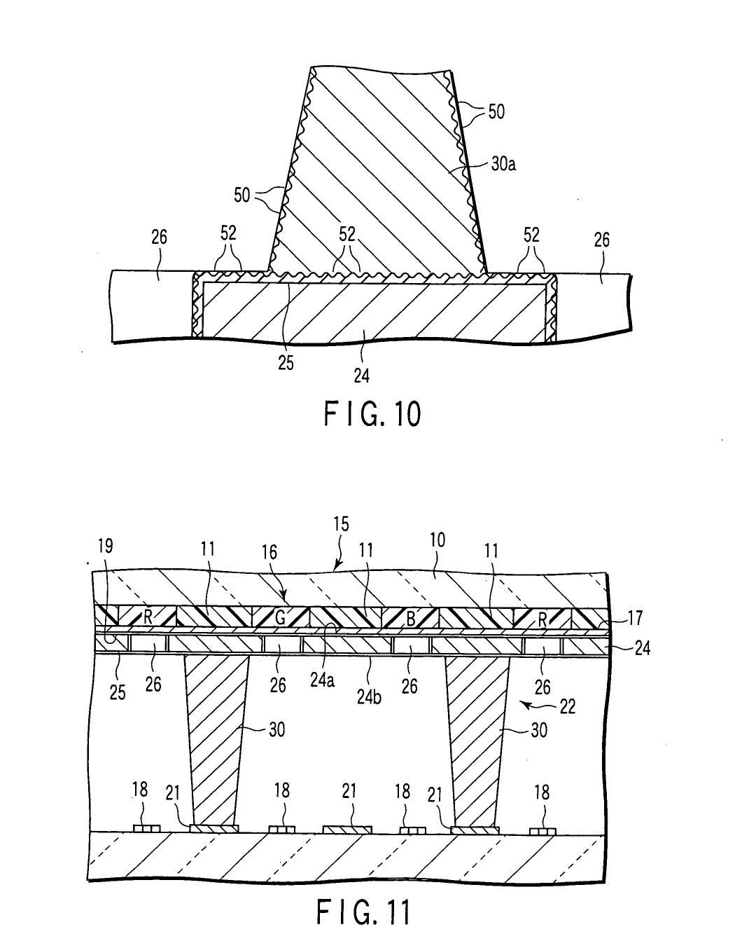

In the first embodiment described above, the minute convexes and concaves 52 is formed in the region of the insulating layer 25 of the support substrate 24 except the region where the first and second spacers 30a, 30b are standingly arranged. However, as shown in a second embodiment of FIG. 10, minute convexes and concaves 52 having Ra of 0.2 to 0.6 μm and Sm of 0.02 to 0.3 mm may be formed on the entire surface of the insulating layer 25, and first and second spacers 30a, 30b may be standingly arranged in the regions where the convexes and concaves are formed. Note that since the other configurations of the second embodiment are the same as those in the first embodiment described above, the same portions are denoted by the same reference numerals and the detailed description thereof will be omitted.

When the SED configured as described above is manufactured, a 0.12 mm thick metal sheet composed of, for example, Fe-50% Ni is used as a support substrate, and electron beam passage apertures 26 are formed to the metal sheet by etching after it is degreased, rinsed, and dried. After the metal sheet is subjected to the blacking treatment in its entirety, a solution containing glass particles is spray coated onto the surface of the support substrate including the inner surfaces of the electron beam passage apertures 26 and died to thereby form the insulating layer 25. Subsequently, the insulating layer 25 is baked and made to glass. Thereafter, the support substrate 24 is dipped in 0.1 to 10 wt % hydrochloric acid liquid, and the entire surface of the insulating layer 25 is partially dissolved. With this operation, the minute convexes and concaves 52 having Ra of 0.2 to 0.6 μm and Sm of 0.02 to 0.3 mm are formed on the entire surface of the insulating layer 25.

Next, the first and second spacers 30a, 30b are formed on the insulating layer 25 of the support substrate 24 by the same method as the first embodiment described above. After the first and second spacers 30a, 30b are baked and made to the glass, they are dipped in a 0.1 to 10 wt % hydrochloric acid liquid, and the surface of the first and second spacers 30a, 30b is partially dissolved. With this operation, minute convexes and concaves 50 having Ra of 0.2 to 0.6 μm and Sm of 0.02 to 0.3 mm are formed on the surface of the first and second spacers 30a, 30b. The depths of the convexes and concaves 50, 52 can be adjusted by adjusting the concentration of hydrochloric acid in the solution, the temperature of the solution, and the dipping time of the above substrate and spacers, or by changing the fluidity of the solution by stirring and the like.

According to the above configuration, the same operation/working-effect as the first embodiment can be obtained and the intimate contact force between the respective spacers and the support substrate 24 is improved. Consequently, the strength of the first and second spacers 30a, 30b can be improved.

In the embodiments described above, although the spacer structure 22 includes the first and second spacers and the support substrate 24 integrally with it, the second spacers 30b may be formed on the second substrate 12. Further, the spacer structure may include only the support substrate and the second spacers, and the support substrate may come into contact with the first substrate.

As shown in FIG. 11, according to a SED of a third embodiment of the present invention, a spacer structure 22 includes a support substrate 24 formed of a rectangular metal sheet and many columnar spacers 30 standingly arranged on one surface of the support substrate integrally with it. The support substrate 24 has a first surface 24a opposing the inner surface of a first substrate 10 and a second surface 24b opposing the inner surface of a second substrate 12, and is arranged in parallel with these substrates. Many electron beam passage apertures 26 are formed in the support substrate 24 by etching or the like. The electron beam passage apertures 26 are arranged to face electron emitting elements 18, and cause the electron beams emitted from the electron emitting elements to pass through them.

The first and second surfaces 24a and 24b of the support substrate 24 and the inner wall surfaces defining the respective electron beam passage apertures 26 are covered with a high resistance film as an insulating layer 25 made of an insulating material mainly composed of glass, ceramics, and the like. The support substrate 24 is arranged such that the first surface 24a is in surface contact with the inner surface of the first substrate 10 through a getter film, a metal back 17, and a phosphor screen 16. The electron beam passage apertures 26 formed in the support substrate 24 oppose phosphor layers R, G, B of the phosphor screen 16. With this arrangement, each of the electron emitting elements 18 faces a corresponding phosphor layer through the electron beam passage aperture 26.

Plural spacers 30 are standingly arranged on the second surface 24b of the support substrate 24 integrally with it. The extended ends of the respective spacers 30 abut against the inner surface of the second substrate 12, here against wirings 21 arranged on the inner surface of the second substrate 12. Each of the spacers 30 is formed in a taper shape whose diameter is gradually reduced from the support substrate 24 side toward the extended end. Each of the spacers 30 is formed to have a slender elliptic cross section in a direction parallel to the surface of the support substrate 24. The spacers 30 has a length of about 1 mm in a longitudinal direction X of the base end thereof located on the support substrate 24 side, a width of about 300 μm in a width direction Y, and a height of about 1.4 mm in an extending direction. The spacers 30 are arranged on the support substrate 24 in a state that its longitudinal direction is in agreement with the longitudinal direction X of a vacuum envelope.

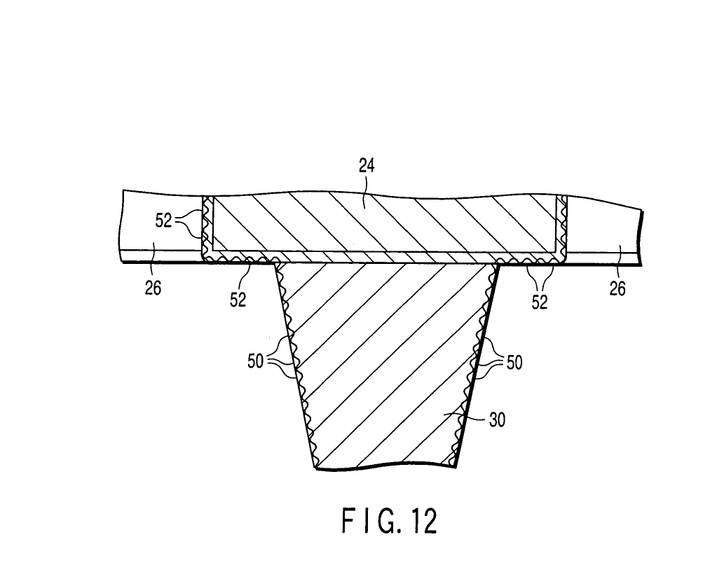

As shown in FIG. 12, minute convexes and concaves 50 having Ra of 0.2 to 0.6 μm and Sm of 0.02 to 0.3 mm are formed on the entire surfaces of the spacers 30. Further, minute convexes and concaves 52 having Ra of 0.2 to 0.6 μm and Sm of 0.02 to 0.3 mm are formed on the insulating layer 25 which is formed on the second surface of the support substrate 24 except the region where the spacers are standingly arranged. Note that the convexes and concaves 52 may be formed on the entire surface of the insulating layer 25, and the spacers 30 may be standingly arranged in the region where the convexes and concaves are formed likewise the second embodiment. Further, the minute convexes and concaves 52 may not be formed on the insulating layer 25 which is formed on the first surface 24a of the support substrate 24.

In the spacer structure 22 configured as described above, the support substrate 24 comes into surface contact with the first substrate 10, and the extended ends of the spacers 30 abut against the inner surface of the second substrate 12. With this arrangement, the atmospheric pressure acting on these substrates is supported by the spacer structure, and the interval between the substrates is maintained at a predetermined value.

Since the other configurations of the third embodiment are the same as those of the first embodiment described above, the same portions are denoted by the same reference numerals and the detailed description thereof will be omitted. The SED and its spacer structure according to the third embodiment can be manufactured by the same manufacturing method as that of the embodiments described above. Further, the third embodiment can also obtain the same operation/working effect as the first embodiment.

The present invention is not limited directly to the embodiments described above, and its components may be embodied in modified forms without departing from the spirit of the invention. Further, various inventions may be formed by suitably combining a plurality of components described in connection with the foregoing embodiments. For example, some of the components according to the foregoing embodiments may be omitted. Furthermore, components according to different embodiments may be combined as required.

In the present invention, the spacers are arranged on the support substrate. However, the support substrate may be omitted, and the spacers may be directly arranged between the first and second substrates. The diameter and height of the spacers, the size, material, and the like of the other components are not limited by the embodiments described above, and may be appropriately selected as necessary. The spacers are not limited to the columnar spacers described above, and plate-shaped spacers may be used. A condition for filling the spacer forming material may be variously selected as necessary. Further, the present invention is by no means limited to the image display device using the surface conduction type electron emitting elements as the electron sources, and can be also applied to an image display device using other electron source such as an electric field emitting type and carbon nanotube.

What is claimed is:

1. An image display device comprising:
an envelope having a first substrate and a second substrate opposed to the first substrate with a gap;
a plurality of pixels arranged in the envelope; and
a plurality of spacers arranged between the first substrate and the second substrate in the envelope to support atmospheric pressure acting on the first and second substrates, convexes and concaves having Ra of 0.2 to 0.6 μm and Sm of 0.02 to 0.3 mm being formed on surfaces of the respective spacers.

2. The image display device comprising:
an envelope having a first substrate and a second substrate opposed to the first substrate with a gap;
a plurality of pixels arranged in the envelope; and
a spacer structure arranged between the first substrate and the second substrate in the envelope to support atmospheric pressure acting on the first and second substrates,
the spacer structure including a support substrate arranged opposite to the first and second substrates and a plurality of spacers standingly arranged on at least one surface of the support substrate, and convexes and concaves having Ra of 0.2 to 0.6 μm and Sm of 0.02 to 0.3 mm being formed on at least one of surfaces of the respective spacers and surfaces of the support substrate.

3. The image display device according to claim 2, wherein the support substrate has a first surface opposing the first substrate and a second surface opposing the second substrate, and
the spacers include a plurality of first spacers standingly arranged on the first surface, respectively, and having extended ends which abut against the first substrate, and a plurality of second spacers standingly arranged on the second surface, respectively, and having extended ends which abut against the second substrate.

4. The image display device according to claim 2, wherein the support substrate has a first surface abutting against the first substrate and a second surface opposing the second substrate with a gap, and
the spacers are standingly arranged on the second surface and have extended ends which abut against the second substrate.

5. The image display device according to claim 2, wherein the surface of the support substrate is covered with an insulation layer, the convexes and concaves are formed on the entire surface of the insulation layer, and the spacers are standingly arranged on the insulation layer on which the convexes and concaves are formed.

6. The image display device according to claim 2, wherein the surface of the support substrate is covered with an insulation layer, the spacers are standingly arranged on the insulation layer, and the convexes and concaves are formed on the entire surface of the insulation layer except the region where the spacers are standingly arranged.

7. A method of manufacturing an image display device comprising an envelope having a first substrate and a second substrate opposed to the first substrate with a gap; a plurality of pixels arranged in the envelope; and a plurality of spacers arranged between the first substrate and the second substrate in the envelope to support atmospheric pressure acting on the first and second substrates, convexes and concaves having Ra of 0.2 to 0.6 μm and Sm of 0.02 to 0.3 mm being formed on surfaces of the respective spacers, the method comprising:
preparing a molding tool having a plurality of spacer forming holes;
filling the spacer forming holes of the molding tool with a spacer forming material;
curing the spacer forming material filled in the spacer forming holes of the molding tool and then separating the spacer forming material from the molding tool;
forming spacers by baking the spacer material separated from the molding tool; and
partially dissolving surfaces of the formed spacers by an acid liquid to form convexes and concaves having Ra of 0.2 to 0.6 μm and Sm of 0.02 to 0.3 mm on the entire surfaces of the spacers.

8. A method of manufacturing an image display device comprising an envelope having a first substrate and a second substrate opposing the first substrate with a gap; a plurality of pixels arranged in the envelope; and a spacer structure arranged between the first substrate and the second substrate in the envelope to support atmospheric pressure acting on the first and second substrates, the spacer structure including a support substrate arranged opposite to the first and second substrates and a plurality of spacers standingly arranged on at least one surface of the support substrate, and convexes and concaves having Ra of 0.2 to 0.6 μm and Sm of 0.02 to 0.3 mm being formed on at least one of surfaces of the respective spacers and a surface of the support substrate, the method comprising:
preparing a molding tool having a plurality of spacer forming holes and a support substrate;
covering a surface of the support substrate with an insulation layer;
filling the spacer forming holes of the molding tool with a spacer forming material;
causing the molding tool filled with the spacer forming material to come into intimate contact with the surface of the support substrate on which the insulation layer is formed, and then curing the spacer forming material;
separating the molding tool and transferring the cured spacer forming material onto the surface of the support substrate;
forming spacers by baking the separated spacer material and the insulation layer; and
partially dissolving the surfaces of the formed spacers and the insulation layer by an acid liquid and forming convexes and concaves having Ra of 0.2 to 0.6 μm and Sm of 0.02 to 0.3 mm on the surfaces of the spacers and the surface of the insulation layer.

9. A method of manufacturing an image display device comprising an envelope having a first substrate and a second substrate opposed to the first substrate at an interval; a plurality of pixels arranged in the envelope; and a spacer structure arranged between the first substrate and the second substrate in the envelope to support atmospheric pressure acting on the first and second substrates, the spacer structure including a support substrate opposing the first and second substrates and a plurality of spacers standingly arranged on at least one surface of the support substrate, and convexes and concaves having Ra of 0.2 to 0.6 μm and Sm of 0.02 to 0.3 mm being formed on at least one of surfaces of the respective spacers and a surface of the support substrate, the method comprising:
preparing a molding tool having a plurality of spacer forming holes and a support substrate;
covering the surface of the support substrate with an insulation layer;
partially dissolving the surface of the insulation layer with an acid liquid and forming convexes and concaves having Ra of 0.2 to 0.6 μm and Sm of 0.02 to 0.3 mm on the surface of the insulation layer;
filling the spacer forming holes of the molding tool with a spacer forming material;
causing the molding tool filled with the spacer forming material to come into intimate contact with the insulation layer, on which the convexes and concaves are formed, of the support substrate, and then curing the spacer forming material;
separating the molding tool and transferring the cured spacer forming material onto the surface of the support substrate;
forming spacers by baking the separated spacer material and the insulation layer; and
partially dissolving the surfaces of the formed spacers by an acid liquid and forming convexes and concaves having Ra of 0.2 to 0.6 μm and Sm of 0.02 to 0.3 mm on the surface of the spacers.
